(19) United States
(12) Patent Application Publication
(10) Pub. No.: US 2026/0050223 A1
(43) Pub. Date: Feb. 19, 2026

(54) APPARATUS AND METHOD FOR OPTICAL INSPECTION OF EUV PELLICLES

(71) Applicant: Taiwan Semiconductor Manufacturing Company, Ltd., Hsinchu (TW)

(72) Inventors: Wei-Huai CHIU, Hsinchu (TW); Yen-Hao LIU, Hsinchu (TW); Cheng-Yuan LIN, Hsinchu (TW); Chueh-Chi KUO, Hsinchu (TW); Han-Lung CHANG, Hsinchu (TW)

(73) Assignee: Taiwan Semiconductor Manufacturing Company, Ltd., Hsinchu (TW)

(21) Appl. No.: 18/808,284

(22) Filed: Aug. 19, 2024

(51) Int. Cl. G03F 7/00; G01N 21/64; G03F 1/62

(52) U.S. Cl. CPC G03F 7/70591; G01N 21/64; G03F 1/62; G03F 7/70033; G03F 7/705; G03F 7/7085

(57) ABSTRACT

An embodiment method of inspecting an EUV pellicle includes generating a plurality of intensity measurements by causing first radiation to impinge on the EUV pellicle, which causes the EUV pellicle to generate second radiation, and measuring an intensity of the second radiation. The method further includes determining, from a plurality of such intensity measurements, a time-dependent intensity increase and predicting a pellicle lifetime based on the time-dependent intensity increase. The first radiation includes wavelengths from 150 nm to 350 nm, from 495 nm to 570 nm, or a white light spectrum. Measuring the intensity of the second radiation further includes measuring a first intensity component of a first wavelength and measuring a second intensity component of a second wavelength, with measured wavelengths chosen from 402 nm, 425 nm, 450 nm, 475 nm, 515 nm, 550 nm, 555 nm, 600 nm, 640 nm, 690 nm, 745 nm, and 855 nm.

### BACKGROUND

In semiconductor device manufacturing, extreme ultraviolet (EUV) lithography is a technique used to make semiconductor device structures. This method employs scanners that utilize electromagnetic radiation in the EUV spectrum, with wavelengths ranging from about one nanometer (nm) to approximately one hundred nm. Unlike earlier optical scanners that use refractive optics (lenses), EUV scanners use reflective optics (mirrors) for projection printing. EUV lithography relies on a laser-produced plasma that emits EUV radiation. This plasma is generated by focusing a high-power laser, such as a CO₂ laser, onto small metallic fuel droplet targets, like tin (Sn) droplets, creating a highly ionized plasma state. The resulting EUV radiation, with a peak emission wavelength of around 13.5 nm or smaller, is collected by a collector and reflected by optics towards a lithography exposure object, such as a semiconductor wafer. Despite significant advancements in recent years, many challenges in the field of EUV lithography persist.

### BRIEF DESCRIPTION OF THE DRAWING

The present disclosure is best understood from the following detailed description when read with reference to the accompanying figures. It is emphasized that, following the standard practice in the industry, various features are not drawn to scale and are used for illustration purposes only. In this regard, the dimensions of the various features may be arbitrarily increased or reduced for clarity of discussion.

FIG. 1 is a vertical cross-sectional view of an extreme ultraviolet EUV lithography system with an EUV radiation source, according to various embodiments.

FIG. 2 is a schematic view of an EUV lithography exposure tool, according to various embodiments.

FIG. 3A is a vertical cross-sectional view of a reflective reticle structure, according to various embodiments.

FIG. 3B is a vertical cross-section view of a reflective reticle structure that is configured to project EUV radiation on a semiconductor device, according to various embodiments.

FIG. 4A is a top view of a pellicle membrane before exposure to EUV radiation, according to various embodiments.

FIG. 4B is a top view of a pellicle membrane after exposure to EUV radiation for a first time duration, according to various embodiments.

FIG. 4C is a top view of a pellicle membrane after exposure to EUV radiation for an additional time duration, according to various embodiments.

FIG. 5 is a plot showing radiation transmittance at two wavelengths vs. time for several types of carbon nanotube (CNT) based materials, according to various embodiments.

FIG. 6 is a vertical cross-sectional view of a system including a reticle pod device and an inspection tool, according to various embodiments.

FIG. 7A is a vertical cross-sectional view of a multi-spectral detector, according to various embodiments.

FIG. 7B is a top view of the multi-spectral detector of FIG. 7A including sensor elements configured to detect multiple wavelengths of electromagnetic radiation, according to various embodiments.

FIG. 8A is a schematic illustration of a spectral control filter having a position-dependent and wavelength-dependent transmission region, according to various embodiments.

FIG. 8B is a schematic illustration of a further spectral control filter having a position-dependent and wavelength-dependent transmission region, according to various embodiments.

FIG. 8C is a schematic illustration of a further spectral control filter having a position-dependent and wavelength-dependent transmission region, according to various embodiments.

FIG. 8D is a plot of reflectivity vs. wavelength for various spectral control filter materials, according to various embodiments.

FIG. 8E is a plot of transmittance vs. wavelength for various spectral control filter materials, according to various embodiments.

FIG. 9 is a bar graph illustrating intensities measured by the multi-spectral detector of FIGS. 7A and 7B, according to various embodiments.

FIG. 10A is a vertical cross-sectional view of a system including a reticle pod device and an inspection tool, according to various embodiments.

FIG. 10B is a vertical cross-sectional view of a further system including a reticle pod device and an inspection tool, according to various embodiments.

FIG. 10C is a vertical cross-sectional view of a further system including a reticle pod device and an inspection tool, according to various embodiments.

FIG. 11A is a vertical cross-sectional view of a further system including a reticle pod device and an inspection tool, according to various embodiments.

FIG. 11B is a vertical cross-sectional view of a further system including a reticle pod device and an inspection tool, according to various embodiments.

FIG. 12 is a flowchart illustrating operations of a method of inspecting a pellicle, according to various embodiments.

FIG. 13 is a flowchart illustrating operations of a further method of inspecting a lithography system component, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B and C” means “A, B and/or C” (A, B, C, A and B, A and C, B and C, or A, B and C), and does not mean one element from A, one element from B and one element from C, unless otherwise described.

Disclosed embodiments are advantageous by providing methods of performing non-destructive inspection of pellicles for EUV lithography while an EUV reticle is installed within an EUV lithography machine or while it is secured within a protective reticle pod. EUV pellicles that contain carbon nanotubes (CNT) have many desirable properties for EUV lithography applications, including high transmittance of EUV radiation, long lifetime, mechanical strength, effective blocking of particulates, and efficient heat dissipation. Despite these advantages, CNT pellicles used in EUV lithography are susceptible to damage from intense EUV radiation. Such damage may contaminate the EUV lithography machine leading to lengthy and expensive repairs. Disclosed embodiments provide methods of predicting pellicle lifetimes using non-destructive radiation based on a correlation between pellicle thickness and/or density and measured transmittance of the non-destructive (i.e., non-EUV) radiation.

In this regard, when a determined thickness and/or density falls below a threshold value, the pellicle is replaced. As such, contamination or damage to other components of the lithography machine or damage to wafers being processed may be prevented. Alternatively, based on a predicted pellicle lifetime, the pellicle can be scheduled to be replaced during the next scheduled routine maintenance to prevent downtime caused by a pellicle rupture.

A pellicle is a thin transparent film stretched over a frame (or is self-supporting) that is attached to (e.g., with an adhesive) or otherwise supported over one side of a photo mask (also called a “reticle”) to protect the photo mask from damage, dust, and/or moisture. The pellicle should be transparent to the radiation source of the lithography process. For example, in EUV lithography, the pellicle should be transparent to EUV radiation and should have high durability. When the reticle is covered by a pellicle, dust or other debris particles generally settle on the pellicle rather than on the reticle. Consequently, when the reticle is imaged on a substrate, particles that are not in the plane of the reticle do not create a focused image on the substrate.

The pellicle is a layer of material that is about 25 nm to 125 nm thick and is transparent to a UV radiation source, such as deep ultraviolet (DUV) radiation (i.e., radiation having a wavelength between 102 nm and 300 nm) or EUV radiation, used in the lithography process. In some embodiments, the pellicle is made of SiC, polysilicon, silicon nitride, or graphene. In various embodiments, described below, the pellicle may also include a layer of a nano-scale material, such as a layer of CNTs.

According to various embodiments, the pellicle is mounted on the reticle by positioning the pellicle on a plurality of studs or fixtures, creating a separation of about 2 mm to 5 mm between the reticle and the pellicle. This separation creates one or more openings, allowing dust particles to enter the enclosure between the reticle and the pellicle. In some embodiments, the pellicle is attached to a mounting fixture, which is secured over the reticle with several studs (e.g., four studs with one at each corner of the pellicle). Openings are present between the pellicle and the reticle where the studs are not located, allowing particles to enter the enclosure. Alternatively, the space between the reticle and the pellicle can be sealed thereby eliminating openings and preventing dust particles from entering the space between the reticle and the pellicle.

EUV lithography is performed in an exposure device, such as an exposure system, under a vacuum environment in some embodiments. Therefore, sealing the openings between the reticle and the pellicle at atmospheric pressure can trap air at atmospheric pressure between the reticle and the pellicle. This trapped air may rupture the pellicle when the combined reticle/pellicle structure is placed inside the vacuum environment of the exposure device. Conversely, if the openings between the reticle and the pellicle are sealed in a vacuum environment, the pellicle may rupture, due to a pressure difference, when the reticle structure is transferred outside of the exposure device and placed under atmospheric pressure. In some embodiments, the distance between the pellicle and the reticle is neither completely sealed nor essentially open, with only a few openings in the pellicle frame.

According to some embodiments, it may be desirable to create some openings, such as holes, between the reticle and the pellicle in the mounting fixture (e.g., a mounting frame) that supports the pellicle over the reticle. In various embodiments, these openings are distributed as separate, unconnected openings in the frame, each with limited dimensions to prevent dust particles from easily entering the enclosure. The holes in the mounting fixture allow pressure exchange between the enclosure and the outside environment, preventing the pellicle from rupturing when the reticle/pellicle structure is transferred into the vacuum environment of the exposure device or out of the vacuum environment into atmospheric pressure. In some embodiments (e.g., for DUV lithography using 193 nm radiation), a pellicle structure with a membrane attached to a frame is used. The frame has a few openings for gas passage between the enclosed space (i.e., the space enclosed by the pellicle) and the outside environment. Due to the higher energy of EUV radiation, the EUV exposure device operates under a higher vacuum environment than the DUV exposure device. Thus, the pellicle structure used in DUV lithography systems may rupture in EUV lithography systems, necessitating increased openings in the frame to allow faster pressure equalization between the enclosed space and the outside. In some embodiments, the pressure inside the DUV or EUV exposure device is between about 3 and 5 Pascal.

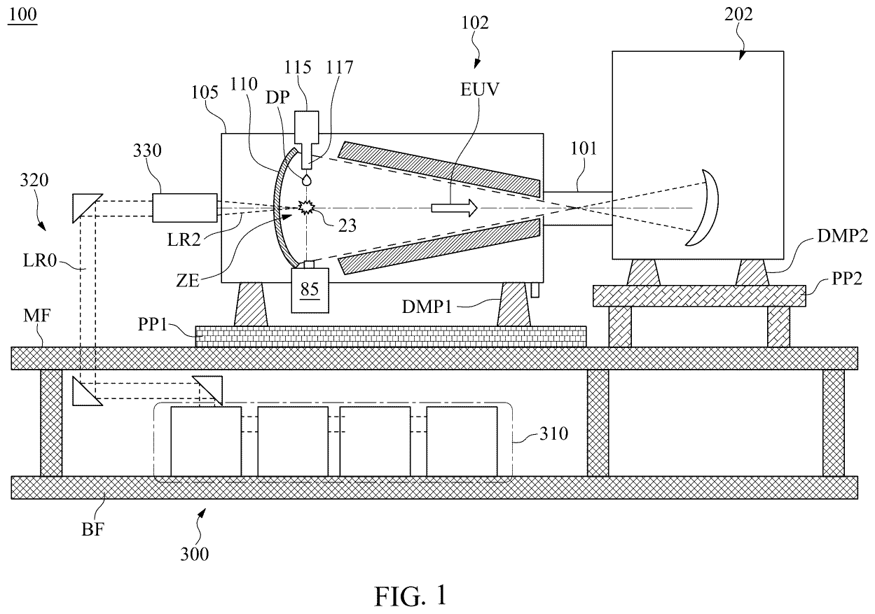

FIG. 1 is a vertical cross-sectional view of an extreme ultraviolet (EUV) lithography system 100 with an EUV radiation source 102, according to various embodiments. The EUV lithography system 100 further includes an exposure device 202, such as a scanner, and an excitation laser source 300. As shown in FIG. 1, in some embodiments, the EUV radiation source 102 and the exposure device 202 are installed on a main floor MF of a clean room, while the excitation laser source 300 is installed in a base floor BF located under the main floor. Each of the EUV radiation source 102 and the exposure device 202 are placed over pedestal plates PP1 and PP2 via dampers DMP1 and DMP2, respectively. The EUV radiation source 102 and the exposure device 202 are coupled to one another by a coupling mechanism, which includes a focusing unit 101.

The EUV lithography system 100 is designed to expose a resist layer, formed over a substrate, to EUV radiation. The resist layer is a material sensitive to the EUV radiation. The EUV lithography system 100 employs the EUV radiation source 102 to generate EUV radiation, such as EUV radiation having a wavelength ranging between about 1 nm and about 50 nm. In an example embodiment, the EUV radiation source 102 generates EUV radiation with a peak wavelength that is approximately 13.5 nm. In this embodiment, the EUV radiation source 102 utilizes a mechanism of laser-produced plasma to generate the EUV radiation.

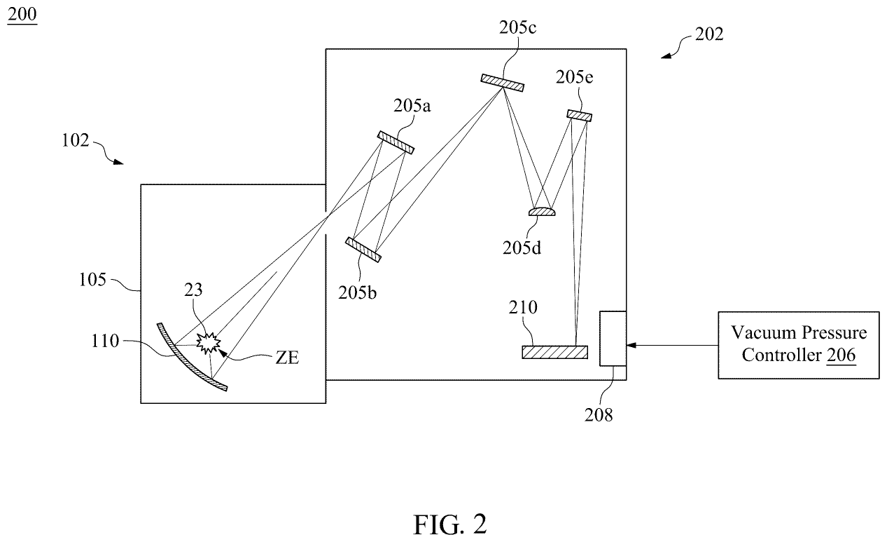

The exposure device 202 includes various reflective optical components, such as convex mirrors, concave mirrors, and flat mirrors (e.g., see FIG. 2). The exposure device 202 further includes a mask-holding mechanism including a mask stage, and a wafer-holding mechanism (e.g., a substrate holding mechanism). The EUV radiation generated by the EUV radiation source 102 is guided by the reflective optical components onto a mask secured on the mask stage (both not shown in FIG. 1). In some embodiments, the mask stage includes an electrostatic chuck (e-chuck) to secure the mask. Because gas molecules absorb EUV radiation, the EUV lithography system 100 is maintained in a vacuum or a low-pressure environment to avoid EUV intensity loss. The exposure device 202 is described in greater detail with reference to FIG. 2, below.

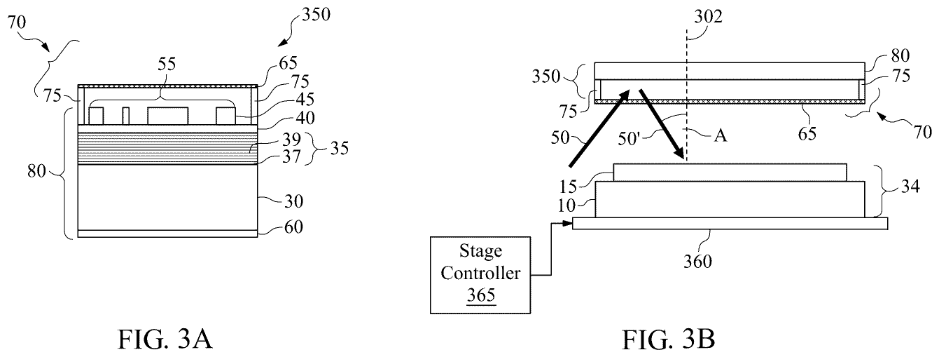

In some embodiments, a reticle is introduced into the exposure device 202, which operates under vacuum conditions. The reticle is positioned above a substrate coated with a photoresist layer, and a pellicle is mounted on the reticle (e.g., see FIG. 3A). Once the reticle/pellicle structure is transferred into the exposure device 202, the pressure inside the enclosure between the reticle and the pellicle is equalized with the vacuum environment of the exposure device 202 through the holes in the mounting fixture (the frame). EUV radiation emitted by the EUV radiation source 102 is directed by optical components to project the mask pattern onto the photoresist layer of the substrate. Subsequently, in certain embodiments, after exposing the photoresist layer of the substrate, the reticle/pellicle structure is removed from the exposure device 202. Upon removal, the pressure within the enclosure between the reticle and the pellicle is equalized with the atmospheric pressure outside the exposure device 202 through the holes in the mounting fixture.

In this disclosure, the terms “mask,” “photomask,” and “reticle” are used interchangeably. In addition, the terms “resist” and “photoresist” are used interchangeably. In some embodiments, the mask is reflective. In some embodiments, the mask includes a substrate with a suitable material, such as a low thermal expansion material or fused quartz. In various examples, the material includes TiO₂ doped SiO₂ or other suitable materials with low thermal expansion. The mask includes multiple reflective layers deposited on the substrate. In some embodiments, the multiple layers include a plurality of film pairs, such as molybdenum-silicon film pairs (e.g., a layer of molybdenum above or below a layer of silicon in each film pair). Alternatively, in other embodiments, the multiple layers include alternating molybdenum-beryllium film pairs or other suitable materials that are configurable to be reflective of EUV radiation. The mask may further include a capping layer, such as ruthenium, formed on the multiple layers for protection. According to various embodiments, the mask further includes an absorption layer, such as a tantalum boron nitride layer, deposited over the multiple layers. The absorption layer is patterned to define a layer of an integrated circuit (IC). Alternatively, another reflective layer may be deposited over the multiple layers and is patterned to define a layer of an integrated circuit, thereby forming an EUV phase shift mask. The mask is described in greater detail with reference to FIG. 3A, below.

The exposure device 202 includes a projection optics module that images the pattern of the mask onto a semiconductor substrate, which has a resist coated thereon and which is secured on a substrate stage of the exposure device 202. The projection optics module generally includes reflective optics. The EUV radiation directed from the mask, carrying the image of the pattern defined on the mask, is collected by the projection optics module, thereby forming an image on the resist.

In various embodiments, the semiconductor substrate is a semiconductor wafer, such as a silicon wafer or other type of wafer to be patterned. The semiconductor substrate is coated with a resist layer that is sensitive to the EUV radiation. Various components, including those described above, are integrated and are operable to perform lithography exposure processes. The EUV lithography system 100 may further include other modules or be integrated with (or be coupled with) other modules.

As shown in FIG. 1, the EUV radiation source 102 includes a droplet generator 115 and a laser-produced plasma collector mirror 110, enclosed by a chamber 105. The droplet generator 115 generates a plurality of target droplets DP, which are supplied into the chamber 105 through a nozzle 117. In some embodiments, the target droplets DP are Sn, Li, or an alloy of Sn and Li. In some embodiments, the target droplets DP each have a diameter in a range from about 10 microns to about 102 microns. For example, in an embodiment, the target droplets DP are Sn droplets, each having a diameter of about 10 microns, about 25 microns, about 50 microns, or any diameter between these values. In some embodiments, the target droplets DP are supplied through the nozzle 117 at a rate in a range from about 50 droplets per second (i.e., an ejection frequency of about 50 Hz) to about 50,000 droplets per second (i.e., an ejection-frequency of about 50 kHz). For example, in an embodiment, target droplets DP are supplied at an ejection frequency of about 50 Hz, about 102 Hz, about 500 Hz, about 1 kHz, about 10 kHz, about 25 kHz, about 50 kHz, or any ejection frequency between these frequencies. The target droplets DP are ejected through the nozzle 117 and into a zone of excitation ZE (e.g., a target droplet location) at a speed in a range from about 10 m/s to about 102 m/s in various embodiments. For example, in an embodiment, the target droplets DP have a speed of about 10 m/s, about 25 m/s, about 50 m/s, about 75 m/s, about 102 m/s, or at any speed between these speeds.

The excitation laser beam LR2 generated by the excitation laser source 300 is a pulsed beam. The laser pulses of laser beam LR2 are generated by the excitation laser source 300. The excitation laser source 300 includes a laser generator 310, laser guide optics 320, and a focusing apparatus 330. In some embodiments, the laser generator 310 includes a carbon dioxide (CO₂) or a neodymium-doped yttrium aluminum garnet (Nd: YAG) laser source with a wavelength in the infrared region of the electromagnetic spectrum. For example, the laser source 310 has a wavelength of 9.4 microns or 10.6 microns in an embodiment. The laser beam LR0 generated by the excitation laser source 300 is guided by the laser guide optics 320 and focused, by the focusing apparatus 330, into the excitation laser beam LR2 that is introduced into the EUV radiation source 102. In some embodiments, in addition to CO₂ and Nd: YAG lasers, the laser beam LR2 is generated by a gas laser including an excimer gas discharge laser, helium-neon laser, nitrogen laser, transversely excited atmospheric (TEA) laser, argon ion laser, copper vapor laser, KrF laser or ArF laser; or a solid state laser including Nd: glass laser, ytterbium-doped glasses or ceramics laser, or ruby laser. In some embodiments, a non-ionizing laser beam (not shown) is also generated by the excitation laser source 300 and the laser beam is also focused by the focusing apparatus 330.

In some embodiments, the excitation laser beam LR2 includes a pre-heat laser pulse and a main laser pulse. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser (main pulse), generating increased emission of EUV radiation compared to when the pre-heat laser pulse is not used.

In various embodiments, the pre-heat laser pulses have a spot size of about 102 microns or less, and the main laser pulses have a spot size in a range of about 150 microns to about 300 microns. In some embodiments, the pre-heat laser and the main laser pulses have a pulse duration in the range from about 10 ns to about 50 ns and a pulse frequency in the range from about 1 kHz to about 102 kHz. In various embodiments, the pre-heat laser and the main laser have an average power in the range from about 1 kilowatt (KW) to about 50 kW. The pulse frequency of the excitation laser beam LR2 is matched with the ejection frequency of the target droplets DP in an embodiment.

The laser beam LR2 is directed through windows or lenses (not shown) into the zone of excitation ZE. The windows or lenses may be made of a suitable material that is substantially transparent to the laser beams. The generation of the laser pulses is synchronized with the ejection of the target droplets DP through the nozzle 117. As the target droplets move through the excitation zone, the pre-pulses heat the target droplets and transform them into low-density target plumes. A delay between the pre-pulse and the main pulse is controlled to allow the target plume to form and expand to an optimal size and geometry. In various embodiments, the pre-pulse and the main pulse have the same pulse duration and peak power. When the main pulse heats the target plume, a high-temperature plasma is generated. The plasma emits EUV radiation, which is collected by the collector mirror 110. The collector mirror 110, which is configured as an EUV collector mirror, further reflects, and focuses the EUV radiation which may be provided to the exposure device 202. A droplet DP that does not interact with the laser pulses is captured by the droplet catcher 85.

One method of synchronizing the generation of a pulse (either or both the pre-pulse and the main pulse) from the excitation laser with the arrival of the target droplet in the zone of excitation is to detect the passage of a target droplet at a given position and use it as a signal for triggering an excitation pulse (or pre-pulse). In this method, if, for example, the time of passage of the target droplet is denoted by to, the time at which EUV radiation is generated (and detected) is denoted by t_{rad}, and the distance between the position at which the passage of the target droplet is detected and a center of the zone of excitation is d, the speed of the target droplet, v_{dp}, is calculated as

$${v}_{dp} = d / ( {t}_{rad} - {t}_{o} ) . \qquad equation ( 1 )$$

Because the droplet generator 115 is expected to reproducibly supply droplets at a fixed speed, once v_{dp} is calculated, the excitation pulse is triggered with a time delay of d/v_{dp} after a target droplet is detected to have passed the given position to ensure that the excitation pulse arrives at the same time as the target droplet reaches the center of the zone of excitation. In some embodiments, because the passage of the target droplet is used to trigger the pre-pulse, the main pulse is triggered following a fixed delay after the pre-pulse. In some embodiments, the value of target droplet speed v_{dp} is periodically recalculated by periodically measuring t_{rad}, if needed, and the generation of pulses with the arrival of the target droplets is resynchronized.

FIG. 2 schematically illustrates an EUV lithography exposure tool (EUVL) 200, according to various embodiments. The EUVL exposure tool 200 features an exposure device 202, designed for exposing a photoresist-coated semiconductor substrate 210 with a patterned beam of EUV radiation. This exposure device 202 is configured as an integrated circuit lithography tool, such as a stepper, scanner, step-and-scan system, direct write system, or a device using a contact and/or proximity mask. It incorporates one or more optical systems (205a, 205b) to illuminate a patterning optic, such as a reticle or reflective mask 205c, with a beam of EUV radiation, thereby producing a patterned beam. This patterned beam is then projected onto the target semiconductor substrate 210 through one or more reduction projection optics (205d, 205e). Additionally, a mechanical assembly (not shown) is utilized to generate controlled relative movement between the target semiconductor substrate 210 and the patterning optic, such as the reflective mask 205c. Furthermore, the EUVL exposure tool 200 includes an EUV radiation source 102, which includes a plasma plume 23 at the zone of excitation ZE that emits EUV radiation within a chamber 105. This radiation is collected and reflected by a collector mirror 110 into the exposure device 202 to irradiate the target semiconductor substrate 210. In some embodiments, the pressure inside the exposure device 202 is monitored by a pressure sensor 208 and regulated by a vacuum pressure controller 206, both of which are integrated into the exposure device 202.

As noted above, because gas molecules absorb EUV radiation, the EUV lithography system 100 (e.g., the exposure device 202) is maintained in a vacuum environment to prevent EUV intensity loss. After transferring the reticle with the pellicle into the exposure device 202, the air pressure in the enclosure between the reticle and the pellicle is equalized with the vacuum environment of the exposure device 202 through the holes in the mounting fixture (the frame), thereby creating a vacuum in the enclosure between the reticle and the pellicle. According to various embodiments, once the photoresist layer of the target semiconductor substrate 210 has been exposed to the EUV radiation, the reticle with the pellicle is transferred out of the exposure device 202. After this transfer, the vacuum in the enclosure between the reticle and the pellicle is equalized with the atmospheric pressure outside the exposure device 202 through the holes in the mounting fixture, restoring atmospheric pressure in the enclosure between the reticle and the pellicle.

FIG. 3A is a vertical cross-sectional view of a reflective reticle structure 350, and FIG. 3B is a vertical cross-sectional view of the reflective reticle structure 350 in a configuration in which EUV radiation (50, 50′) is projected on a semiconductor device 34, according to various embodiments. FIG. 3A shows a cross-sectional view of a reflective reticle structure 350 that includes a reticle 80, also known as a reflective mask. As noted, the terms “mask,” “photomask,” and “reticle” may be used interchangeably. In some embodiments, the reticle 80 functions as a reflective mask and is an integral part of the reflective reticle structure 350. This reflective reticle structure 350 corresponds to the reflective mask 205c depicted in FIG. 2 and is utilized within the exposure device 202 shown in FIG. 2.

The reticle 80 includes a substrate 30, reflective multiple layers (ML) 35 deposited on the substrate 30, a conductive backside coating 60, a capping layer 40, and an absorption layer 45. In some embodiments, the substrate 30 is made of TiO₂-doped SiO₂ or other materials having a relatively low coefficient of thermal expansion. In other embodiments, the substrate 30 includes fused quartz, with a thickness ranging from about 6 mm to about 7 mm. In various embodiments, the ML 35 includes a plurality of film pairs, such as molybdenum-silicon film pairs, where a molybdenum layer 39 is placed above or below a silicon layer 37 in each film pair. In some embodiments, the ML 35 includes 40 to 50 pairs of these layers, with each molybdenum layer 39 having a thickness of 3 nm and each silicon layer 37 having a thickness of 4 nm, resulting in an overall ML thickness between 280 nm and 350 nm. Alternatively, in other embodiments, the ML 35 includes molybdenum-beryllium film pairs or other suitable materials designed that are highly reflective of EUV radiation.

As shown in FIG. 3A, the reticle structure 350 further includes a pellicle structure 70 that includes a pellicle 65 that is attached to the reticle 80 with a support structure 75. The pellicle 65 is formed either as a free-standing structure or as a thin membrane attached to a frame (not shown). As described above, in various embodiments, the pellicle 65 includes a layer of CNTs. Various support structures 75 may be provided in respective embodiments. For example, in some embodiments, the support structure 75 is a frame structure. In other example embodiments, the support structure 75 includes a plurality of spacer structures.

The capping layer 40, which may be made of ruthenium or silicon, is disposed on the ML 35 for protection and has a thickness of 2.5 nm or 4 nm in some embodiments. The absorption layer 45, which can include a tantalum boron nitride (TaBN) layer, is deposited over the ML 35 and the capping layer 40. This absorption layer 45 is patterned with features 55 to define the layout pattern for an integrated circuit (IC) layer. The backside coating 60, which may include chromium nitride or tantalum boride, has a thickness ranging from 20 nm to 102 nm in various embodiments. In some embodiments, another reflective layer may be deposited over the ML 35 and patterned to form an EUV phase shift reticle. The absorption layer 45 may include one or a combination of TaBO, TaBN, TaNO, and TaN, with a thickness between 50 nm and 70 nm, in other embodiments.

FIG. 3B is a vertical cross-section view of a reflective reticle 80 structure that is configured to project EUV radiation on a semiconductor device 34, according to various embodiments. The semiconductor device 34 includes a photoresist layer 15 disposed on a semiconductor substrate 10. FIG. 3B also depicts a radiation beam 50 generated by an EUV radiation source, such as the EUV radiation source 102 shown in FIG. 1. This radiation beam 50 is directed at the reticle 80, which acts as a reflective photomask. The reflected radiation beam 50′ from the photomask 80 is then incident on the photoresist layer 15. The incident angle of the radiation beam 50′, defined relative to a line 302 perpendicular to the top surface of the semiconductor substrate 10, is denoted as angle A. As illustrated in FIG. 3B, both the incident radiation beam 50 and the reflected radiation beam 50′ pass through the pellicle 65 of the pellicle structure 70.

In some embodiments, the semiconductor substrate 10, consistent with the semiconductor substrate 210 shown in FIG. 2, is mounted on a stage 360. This stage 360 is coupled to and controlled by a stage controller 365, which moves the semiconductor device 34 to expose different locations on the device. This setup ensures precise exposure of the photoresist layer at various positions on the semiconductor substrate, facilitating accurate pattern transfer during the lithography process.

The pellicle 65 generally should have high transparency and low reflectivity. In UV or DUV lithography, the pellicle 65 is made of a transparent resin in some embodiments. However, in EUV lithography, a resin-based film is not suitable, and a non-organic material such as polysilicon, silicide, or metal film is used instead. Carbon nanotubes (CNTs) are among the materials suitable for an EUV pellicle 65, as they exhibit high EUV transmittance exceeding 96.5%. A pellicle structure 70 for an EUV reflective mask generally should have the following properties: (1) Long lifetime in an environment rich in hydrogen radicals during EUV stepper/scanner operations; (2) Strong mechanical strength to minimize sagging effects during vacuum pumping and venting operations; (3) Effective blocking of particles larger than about 20 nm (known as killer particles); and (4) Efficient heat dissipation to prevent thermal damage from EUV radiation. Other nanotubes made from non-carbon-based materials can also be used for an EUV photomask pellicle. In some embodiments, a nanotube is a one-dimensional elongated tube with a diameter ranging from about 0.5 nm to about 100 nm. In this context, a pellicle for an EUV photomask includes a network membrane composed of numerous nanotubes forming a mesh structure.

According to various embodiments, CNTs are synthesized using various methods that involve carbonaceous precursor materials. One approach is chemical vapor deposition (CVD), where hydrocarbon gases such as methane or ethylene are decomposed at high temperatures (e.g., in the range 600-900° C.) in the presence of a catalyst, such as transition metals like iron, nickel, or cobalt supported on substrates such as silicon or quartz. During CVD, carbon atoms nucleate and grow into nanotubes on the catalyst surface, forming aligned or randomly oriented structures depending on the growth conditions.

Once synthesized, carbon nanotubes are collected and processed into a membrane suitable for use as a pellicle in EUV lithography. The formation of a CNT-based pellicle membrane involves several steps: first, the nanotubes are dispersed in a suitable solvent or suspension to create a uniform solution. This dispersion can be enhanced using surfactants or functionalization to improve compatibility and stability. Next, the dispersed nanotubes are deposited onto a substrate or template that serves as a support structure for the pellicle 65. Techniques such as spin coating, spray coating, or filtration are employed to achieve a dense and even distribution of nanotubes across the substrate. This step ensures the mechanical integrity and uniformity of the membrane.

Subsequently, the deposited nanotubes are treated to remove residual solvents and to bond them together, either through physical entanglement or chemical interactions, forming a cohesive and robust network. Thermal annealing or chemical cross-linking may be applied to enhance the structural stability and adhesion of the nanotube network. Finally, the substrate with the adhered nanotube membrane undergoes further processing to optimize its optical properties, such as transparency and reflectivity, crucial for its application as a pellicle in EUV lithography. Quality control measures ensure that the pellicle meets stringent performance requirements, including high EUV transmittance, low reflectivity, mechanical durability under vacuum conditions, and resistance to particle contamination.

Despite the above-described advantages, CNT pellicles used in EUV lithography are susceptible to damage from the intense EUV radiation environment in several ways. Firstly, EUV radiation carries substantial energy, which, when absorbed by carbon nanotubes, can induce significant heating effects. This thermal stress may cause the nanotubes to expand, deform, or even break down structurally over time. Additionally, EUV radiation can initiate oxidation processes on the surface of carbon nanotubes, leading to the formation of oxygen-containing groups that alter the optical properties and reduce EUV transmittance of the pellicle. Moreover, the high-energy EUV photons can directly strike the nanotube surface, causing sputtering and erosion by ejecting atoms or molecules from the material. This gradual erosion can reduce the thickness of the pellicle membrane, compromising its mechanical strength and effectiveness in blocking particles.

Furthermore, EUV radiation induces electron emission and charge accumulation on the pellicle's surface, which can lead to electrostatic forces that deform or detach the pellicle from its support structure. Lastly, EUV photons can trigger photochemical reactions within the nanotube material, resulting in chemical bond formations or structural changes that degrade the pellicle's optical and mechanical properties over time. These damage mechanisms underscore the challenges in maintaining the durability and reliability of CNT-based pellicles in semiconductor lithography applications.

The rupture of a carbon nanotube (CNT) pellicle in an extreme ultraviolet (EUV) lithography system can have significant detrimental effects on semiconductor manufacturing processes. When a pellicle breaks, it can release particles into the lithography environment. These particles can contaminate critical components such as EUV mirrors, lenses, and the semiconductor substrate itself. Contamination introduces defects into the patterning process, leading to yield loss and potentially rendering entire batches of semiconductor wafers unusable. The presence of foreign particles on the reticle or substrate can cause variations in pattern fidelity, resulting in defective integrated circuits and increased production costs.

Moreover, the dispersal of pellicle particles throughout the lithography system poses risks beyond immediate production impacts. These particles can adhere to sensitive optical surfaces and degrade their performance over time. Accumulated contamination may necessitate frequent system maintenance and cleaning, leading to downtime and reduced throughput. In worst-case scenarios, particle-induced defects can propagate through subsequent manufacturing steps, impacting device reliability and performance in the final product. Detecting pellicle breakage earlier in the manufacturing process is desirable, as the cleanup and system restoration process to bring the EUV lithography system back online can be lengthy (approximately 9 days). The disclosed embodiments propose integrating sensors at multiple stages of the EUV lithography system, in addition to those already present at the EUV exposure stage, to detect pellicle damage promptly and mitigate contamination risks effectively.

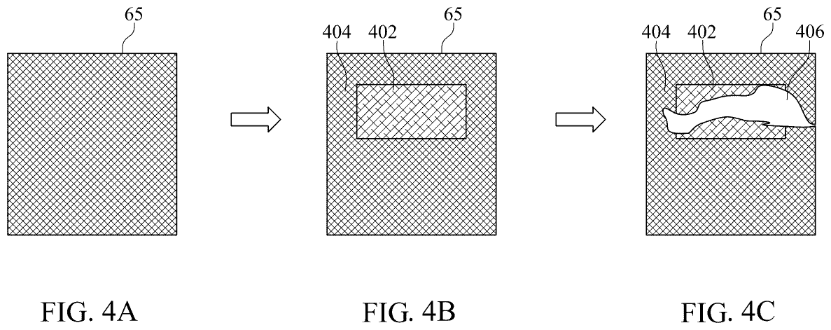

FIG. 4A is a top view of a pellicle 65 before exposure to EUV radiation, according to various embodiments. FIG. 4B is a top view of the pellicle 65 after exposure to EUV radiation for a first time duration, and FIG. 4C is a top view of the pellicle 65 after exposure to EUV radiation for an additional time duration, according to various embodiments. Before exposure to EUV radiation, the pellicle 65 of FIG. 4A may have a uniform appearance when viewed with visible light. However, on a microscopic scale, the pellicle 65 may have various irregularities, defects, and other non-uniformities that may provide nucleation sites for EUV radiation-induced damage.

As shown in FIG. 4B, after exposure to EUV radiation for the first time duration, an exposure region 402 may develop that has different material/mechanical properties from that of an unexposed region 404. For example, after a few hours of exposure to EUV radiation, the pellicle 65 may become thinner and/or may become mechanically damaged (e.g., may develop cracks, holes, etc.). Further, the optical properties of the pellicle 65 may be altered in the exposure region 402. For example, the optical transmissivity of the pellicle 65 may increase with decreasing density and thickness of the pellicle 65. As shown in FIG. 4C, damage in the exposure region 402 may increase with prolonged exposure to EUV radiation such that eventually a rupture 406 may occur. Such a rupture 406 may occur after several days of continuous exposure to EUV radiation. To avoid such damage, various systems and methods are described below that allow early detection of damage to the pellicle 65.

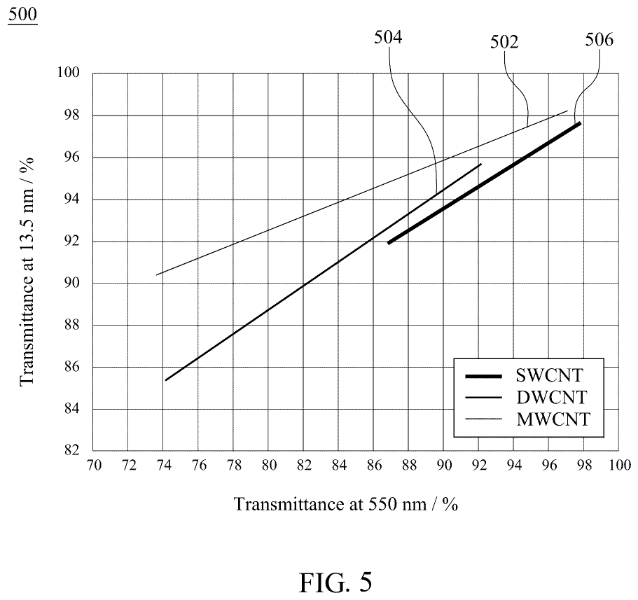

FIG. 5 is a plot showing transmittance of radiation at two wavelengths for several types of CNT materials, according to various embodiments. Plotted on the vertical axis is transmittance at a wavelength of 13.5 nm, which is an EUV wavelength, vs. transmittance at a wavelength of 550 nm, which is a wavelength in the visible spectrum. The first curve 502 corresponds to materials that include single-walled CNTs, the second curve 504 corresponds to materials that include double-walled CNTs, and the third curve 506 corresponds to materials that include multi-walled CNTs. The trend of increasing transmittance at both wavelengths (13.5 nm, 550 nm) corresponds to various material samples having decreasing thickness and/or density.

The transmittance of EUV radiation through a CNT pellicle can be tuned by varying the density or the amount of CNTs within the pellicle 65. Depending on the fabrication approach, the CNT areal density can be adjusted by either varying the CNT collection time during CVD synthesis or by modifying the amount of CNT material collected during vacuum filtration from the solution. Spectrometry in the visible spectrum range may be used and provides a nondestructive method to characterize free-standing CNT films. For example, according to some embodiments, the absorbance of free-standing CNT films at 550 nm can be experimentally correlated to the CNT film thickness without breaking the free-standing CNT film for cross-sectional thickness analysis.

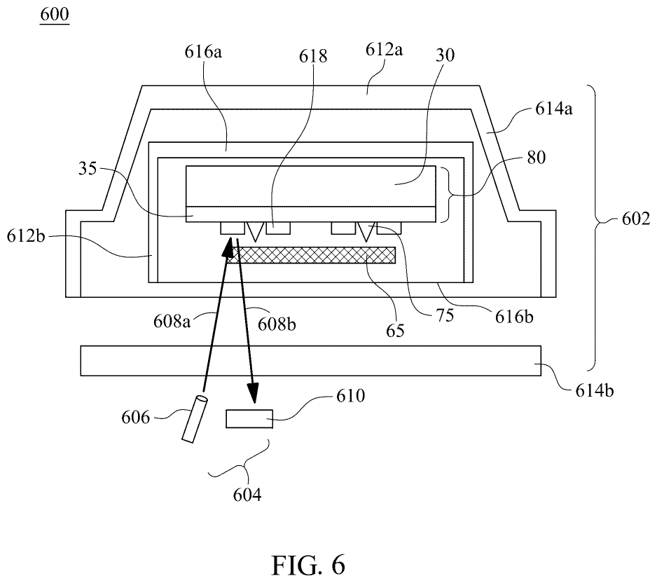

FIG. 5 illustrates a linear correlation between a CNT pellicle's transmittance at 13.5 and 550 nm for different CNT types. The coefficient of this linear correlation depends on the CNT pellicle composition (CNT type, size, and purity) and film microstructure (packing density and bundling). Knowing this relation for a specific CNT type enables tuning of the CNT density during the fabrication process for a specific target EUV transmittance. Such a correlation also provides an opportunity to use non-destructive (e.g., visible, or infrared) radiation to inspect a pellicle 65. In this regard, a prediction regarding the mechanical integrity of a pellicle 65, in terms of its thickness and/or density, may be determined by monitoring a time-dependent increase in transmittance, as described in greater detail with reference to FIGS. 6A to 11B, below.

FIG. 6 is a vertical cross-sectional view of a system 600 including a reticle pod device 602 and an inspection tool 604, according to various embodiments. The inspection tool 604 includes a source 606 of first radiation 608a and a detector 610 of second radiation 608b, which is generated by the pellicle 65 in response to the interaction with the first radiation. According to some embodiments, the source 606 is configured to generate first radiation 608a with various non-destructive (e.g., visible) wavelengths, as described in greater detail below.

As shown in FIG. 6, the reticle pod device 602 is configured to store an EUV reticle 80 that may be similar to the reticle EUV reticle 80 described above with reference to FIGS. 3A and 3B. The reticle 80 includes a substrate 30 formed of a low thermal expansion material, such as low thermal expansion glass or quartz (e.g., fused silica or fused quartz). This substrate 30 transmits light at visible wavelengths, near-infrared wavelengths, and a portion of the ultraviolet spectrum. However, the substrate 30 absorbs EUV and DUV wavelengths near the EUV. In certain embodiments, the substrate 30 is 152 mm×152 mm (or 150 mm×150 mm) with a thickness of about 20 mm and is square or rectangular in various embodiments. According to certain embodiments, the reticle 80 also includes an ML stack 35, as described with reference to FIG. 3A, above.

The reticle pod device 602 includes an outer pod 612a and an inner pod 612b enclosed by the outer pod 612a. The outer pod 612a includes an outer shell 614a and an outer door 614b, while the inner pod 612b includes an inner cover 616a and inner plate 616b. The EUV reticle 80 is placed in the inner pod 612b face down (with the absorber layer 45 (e.g., see FIG. 3a) facing down toward the outer door 614b). The inner plate 616b of the inner pod 612b includes one or more supports (not shown) to support the front (downward-facing) surface of the reticle 80. Similarly, the inner cover 616a of the inner pod 612b includes one or more restraining supports (also not shown) to support the backside (upward-facing side) of the reticle 80. In some embodiments, four restraining supports (not shown) support the respective four corners of the reticle 80.

As further shown in FIG. 6, the inspection tool 604 is configured to cause the first radiation 608a to impinge on the pellicle 65 while the reticle 80 (including pellicle 65 supported by support structures 75) is securely stored in the reticle pod device 602. As such, the inner plate 616b may be configured to be transparent to the first radiation 608a. Similarly, in some embodiments, the outer door 614b may also be configured to be transparent to the first radiation 608a. Alternatively, in embodiments in which the outer door 614b is not transparent, the outer door 614b may be removed from the reticle pod device 602 during testing operations of the inspection tool 604. As shown in FIG. 6, the first radiation 608a may pass through the pellicle 65 and may then reflect from the reticle 80. In some embodiments, the first radiation 608a may reflect off a surface of the ML 35. Alternatively, in some embodiments, the reticle 80 may further include various reflective surfaces 618 that may be configured to reflect the first radiation 608a such that the first radiation 608a once again passes back through the pellicle 65.

The source 606 of first radiation 608a may be a laser, a light-emitting diode, a lamp, etc., that may be configured to generate first radiation 608a of various non-destructive wavelengths. For example, the first radiation 608a may include wavelengths that are from 150 nm to 350 nm (i.e., deep ultraviolet radiation covering parts of the UVA, UVB, and UVC bands) or wavelengths from 495 nm to 570 nm (visible light). In other embodiments, the source 606 may be a broad-spectrum source that may generate white light. As described above with reference to FIG. 5, there is a correlation between the transmittance of the pellicle 65 to EUV radiation and the corresponding transmittance of visible light. Thus, as an inspection method, it is advantageous to consider the interaction of first radiation 608a, having various non-EUV wavelengths, with the pellicle 65. As such, in various embodiments, the detector 610 may be configured to detect multiple wavelengths within the visible and infrared spectrum. For example, in certain embodiments, the detector 610 may be configured to detect second radiation 608b having two or more wavelengths including 402 nm, 425 nm, 450 nm, 475 nm, 515 nm, 550 nm, 555 nm, 600 nm, 640 nm, 690 nm, 745 nm, and 855 nm.

As described above, the transmittance of a pellicle 65 may increase over time due to damage suffered by the pellicle 65 due to exposure to EUV radiation. Thus, a lifetime of the pellicle 65 may be predicted by measuring the transmittance over time. Based on the correlation shown in FIG. 5, the measurement of transmittance may be performed non-destructively by using a source 606 that generates non-EUV first radiation 608a. Thus, a method of predicting the lifetime of a pellicle 65 may be performed as follows. According to various embodiments, the method includes generating a plurality of intensity measurements by (1) causing first radiation 608a to impinge on the pellicle 65, which causes the pellicle 65 to generate a component of the second radiation 608b, and (2) measuring an intensity of the second radiation 608b. As described above, since the first radiation 608a reflects off the reticle 80, the second radiation also includes a component of the reflected first radiation 608a as well as any radiation generated by the pellicle 65 in response to interaction with the first radiation 608a. The method further includes (3) determining, from the plurality of intensity measurements, a time-dependent intensity increase, and (4) predicting a pellicle lifetime based on the time-dependent intensity increase.

In response to the first radiation 608a, the pellicle 65 generates a component of the second radiation 608b to have various wavelengths, depending on the wavelength of the first radiation 608a. As such, according to various embodiments, it is advantageous to measure more than a single wavelength component of the second radiation 608b. For example, in some embodiments, the above-described method includes measuring a first intensity component of a first wavelength and measuring a second intensity component of a second wavelength of the second radiation 608b. For example, as shown in FIG. 5, the transmittance at 550 nm shows a significant correlation between with the transmittance of the EUV wavelength 13.5 nm. Thus, it may be advantageous to measure at least an intensity of transmittance of the second radiation 608b at 550 nm. In further embodiments, the method includes measuring an intensity of transmittance of various other wavelengths including two or more of 402 nm, 425 nm, 450 nm, 475 nm, 515 nm, 550 nm, 555 nm, 600 nm, 640 nm, 690 nm, 745 nm, and 855 nm.

The second radiation 608b is generated by interactions of the first radiation 608a with the material (e.g., CNTs) of the pellicle 65. The interactions include absorption of the first radiation 608a at certain frequencies. As such, the second radiation 608b may include components of the first radiation 608a that are not absorbed by the pellicle 65. In addition to absorption, the interactions of the pellicle 65 with the first radiation 608a may include stimulated emission due to electronic and vibrational excitations. Thus, even if the first radiation 608a includes only a single wavelength, the second radiation 608b may include one or more wavelengths that are different from the wavelength of the first radiation 608a. For example, if the first radiation 608a includes a single wavelength, the second radiation 608b may include one or more wavelengths that are longer or shorter than the wavelength of the first radiation 608a.

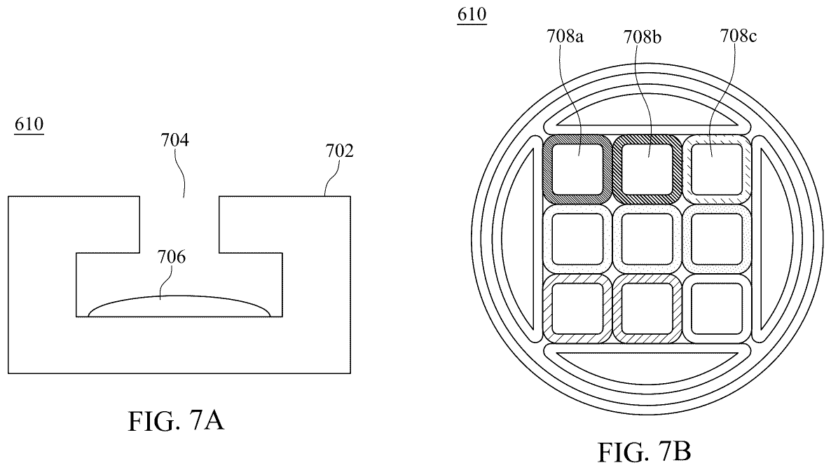

Thus, according to various embodiments, it may be advantageous to measure a plurality of wavelengths of the second radiation 608b. For example, a first wavelength and a second wavelength of the second radiation 608b may be different than a third wavelength of the first radiation 608a in some embodiments. Thus, according to various embodiments, the detector 610 may be configured as a multi-spectral photodetector, as described in greater detail with reference to FIGS. 7A and 7B, below.

FIG. 7A is a vertical cross-sectional view of a multi-spectral detector 610, and FIG. 7B is a top view of the multi-spectral detector of FIG. 7A that includes sensor elements configured to detect multiple wavelengths of electromagnetic radiation, according to various embodiments. As shown in FIG. 7A, the multi-spectral detector 610 includes an enclosure 702 having an aperture 704 that allows electromagnetic (e.g., UV, visible, infrared) radiation to enter the detector 610. The detector 610 further includes a lens 706 that focuses the electromagnetic radiation such that the radiation is provided to one or more photodetectors. In addition to the lens 706, the detector 610 further includes an array of filters or a diffraction grating that separates incoming light into distinct spectral components. Each component is then directed to a dedicated photodetector, which converts the light intensity into an electrical signal. The detector 610 further includes processing circuits that are configured to process the resulting data to generate a spectral profile of the received radiation.

As shown in FIG. 7B, the detector 610 includes a plurality of detection regions (708a, 708b, 708c . . . ) that are configured to detect respective spectral components of the incoming radiation. Each of the spectral regions (708a, 708b, 708c . . . ) includes a spectral filter formed over a photodetector that is configured to detect a particular band of the spectrum corresponding to the portion of the spectrum that is transmitted by the filter. For example, in certain embodiments, the first detection region 708a is configured to detect a first wavelength, the second detection region 708b is configured to detect a second wavelength, the third detection region is configured to detect a third wavelength, etc.

According to various embodiments, the detector 610 is constructed by integrating an array of photodetectors, each tuned to specific spectral bands. These photodetectors are based on semiconductor materials such as silicon, which are sensitive to different wavelengths of light depending on their doping and structure. The detector 610 is configured to capture data from a broad spectrum, including visible, ultraviolet (UV), and near-infrared (NIR) regions. This capability enables the precise characterization of light sources and the identification of various materials based on their spectral signatures.

Each photodetector in the array is configured to respond to a particular wavelength range, capturing the intensity of light in that band. According to various embodiments, the photodetectors are arranged in a compact, grid-like pattern on a substrate. The photodetectors are then connected to readout circuitry that converts the analog signals from the detectors into digital data. According to various embodiments, the entire assembly is packaged onto a circuit board, for example, using surface-mount technology (SMT) for compactness and reliability. According to various embodiments, the circuit board includes additional components such as amplifiers, analog-to-digital converters, and microcontrollers to process and transmit the spectral data. The packaging ensures that the optical path is clear and free of obstructions. For example, in some embodiments, the aperture 704 includes a protective cover or lens (not shown) to shield the sensitive components while allowing light to reach the photodetectors effectively.

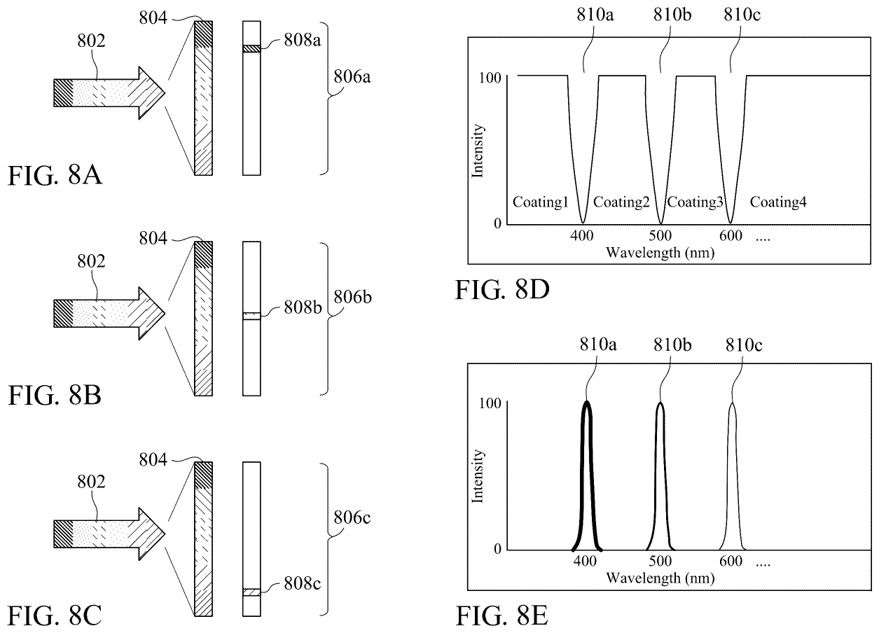

FIGS. 8A to 8C are schematic illustrations of spectral control filters that each have position-dependent and wavelength-dependent transmission regions, according to various embodiments. FIG. 8D is a plot of reflectivity vs. wavelength for various spectral control filter materials and FIG. 8E is a plot of transmittance vs. wavelength for various spectral control filter materials, according to various embodiments. As shown in each of FIGS. 8A to 8C, incoming radiation 802 may have a broad spectrum 804 that may contain a discrete or continuous band of wavelengths. FIG. 8A illustrates a first spectral control filter 806a that allows a first wavelength to be transmitted in a particular first transmission region 808a. Similarly, FIGS. 8B and 8C illustrate a second spectral control filter 806b and a third spectral control filter 806c, respectively. Each of the second spectral control filter 806b and the third spectral control filter 806c are configured to allow respective second and third wavelengths to be transmitted in respective transmission regions (808b, 808c).

In this regard, the first spectral control filter 806a may be configured such that the first transmission region 808a is located over a first sensor that is configured to detect the corresponding wavelength that is transmitted by the first spectral control filter 806a. Similarly, the transmission regions (808b, 808c) may be located over respective second and third sensors that are configured to detect the corresponding respective wavelengths.

According to various embodiments, the spectral control filters (806a, 806b, 806c) are constructed using various techniques to achieve precise wavelength discrimination. One method is the use of thin-film interference coatings. In this technique, multiple layers of dielectric materials with different refractive indices are deposited onto a substrate. By carefully controlling the thickness and number of these layers, interference effects are created that allow only certain wavelengths of light to pass through while reflecting or absorbing others. This results in a filter with sharp spectral cutoffs and high transmission within the desired wavelength range. As shown in FIG. 8D, various coatings (e.g., coating 1, coating 2, coating 3, coating 4) may be used to cover different respective portions of the radiation spectrum.

Another approach to constructing spectral control filters involves using absorption-based materials. These materials are selected based on their ability to absorb specific wavelengths of light while transmitting others. The absorption characteristics are tuned by selecting the appropriate materials and combining them in precise proportions. These filters can be fabricated as standalone components or integrated directly onto the photodetectors in a multi-spectral array. In addition to thin-film and absorption-based filters, diffraction gratings may also be used in some multi-spectral detectors. A diffraction grating is an optical component with a regular pattern of lines or grooves that disperses incoming light into its constituent wavelengths. By positioning the grating correctly relative to the photodetector array, different wavelengths can be directed to specific photodetectors, achieving the desired spectral separation.

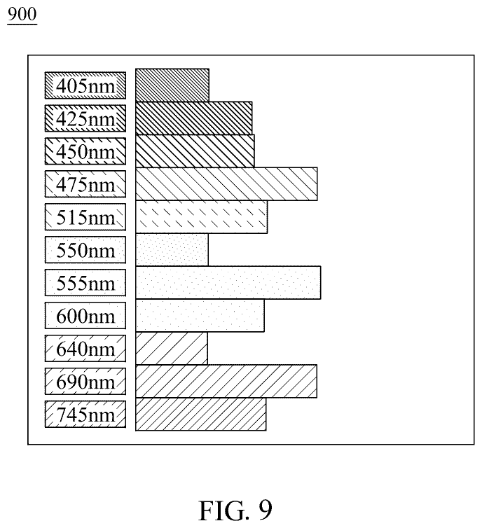

FIG. 9 is a bar graph illustrating intensities measured by the multi-spectral detector of FIGS. 7A and 7B, according to various embodiments. The length of each horizontal bar in FIG. 9 corresponds to a measured intensity for a given spectral component. In this example embodiment, an intensity value is measured for each of the following wavelengths: 402 nm, 425 nm, 450 nm, 475 nm, 515 nm, 550 nm, 555 nm, 600 nm, 640 nm, 690 nm, 745 nm, and 855 nm. The specific values of the measured intensities depend on the material under consideration and on the wavelength or wavelengths of the first radiation 608a. As shown, three wavelengths (475 nm, 555 nm, 690 nm) have the strongest intensity values. Thus, one or more of these wavelengths (475 nm, 555 nm, 690 nm) may be used in a method of measuring the thickness and/or density of a pellicle 65, as suggested in FIG. 5 for 555 nm.

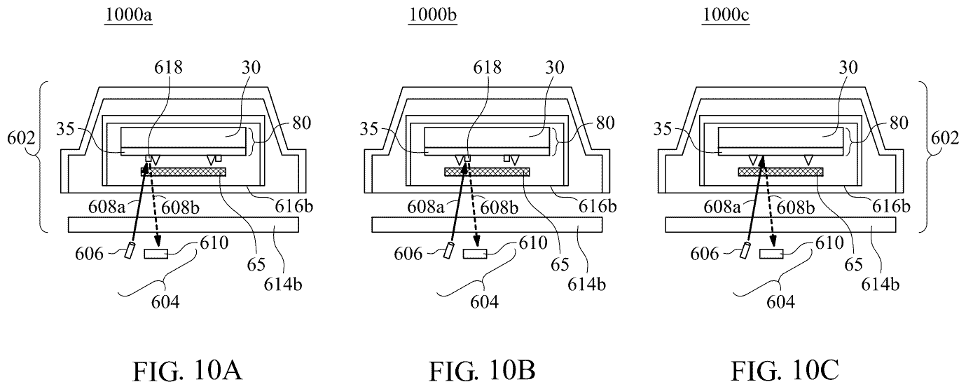

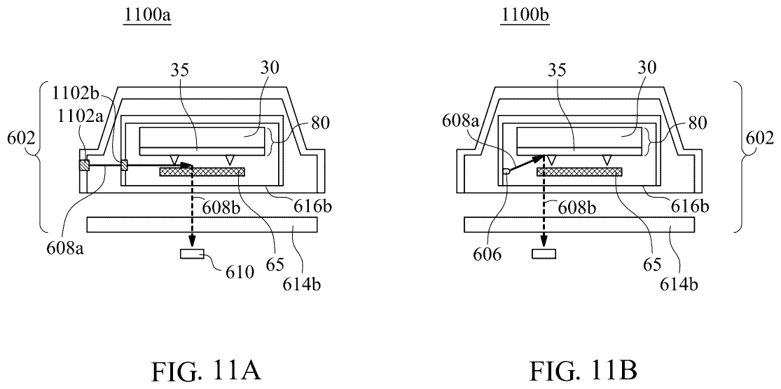

FIGS. 10A to 11B are vertical cross-sectional views of systems (1000a to 1100b) each including a reticle pod device 602 and an inspection tool 604, according to various embodiments. Each of the systems (1000a to 1100b) is similar to the system 600 of FIG. 6 and includes a reticle 80, having a pellicle 65, stored within a reticle pod device 602. The differences between systems (1000a to 1100b) relate to the placement and configuration of the source 606 of first radiation 608a and the detector 610 of second radiation 608b. For example, in systems 1000a, 1000b, and 1000c, the source 606 and detector 610 are located externally to the reticle pod device 602, while in system 1100b of FIG. 11B, the source 606 is located internally to the reticle pod device 602. For example, in systems 1000a, 1000b, and 1000c the source 606 may be a laser, an LED, a lamp, etc., located externally to the reticle pod device 602, while in system 1100b of FIG. 11B, the source 606 may be an LED or other device that is sufficiently small to be housed within the reticle pod device 602.

Each of systems 1000a, 1000b, and 1000c are configured to allow first radiation 608a and second radiation 608b to be transmitted through the inner plate 616b and, in other embodiments, through both the inner plate 616b and the outer door 614b. Similarly, systems 1100a and 1100b are configured to allow the second radiation 608b to be transmitted through the inner plate 616b and through the outer door 614b. In contrast to systems 1000a, 1000b, and 1000c, however, in systems 1100a and 1100b, the first radiation 608a is not introduced through inner plate 616b or the outer door 614b. For example, as described above, in system 1100b the first radiation 608a may be generated by a source 606 that is located within the reticle pod device 602. Alternatively, as shown in FIG. 11A, in system 1100a the first radiation 608a may be introduced through one or more transparent windows (1102a, 1102b) formed in walls of the inner and outer pods from a source (not shown) located externally to system 1100a.

Each of systems 1000a to 1100b allows inspection of a pellicle 65 that is stored in a reticle pod device 602 using non-destructive radiation. Alternatively, a similar system may be installed within an EUV lithography system 100. For example, a source 606 of first radiation 608a and a detector 610 of second radiation 608b may be installed within the exposure device 202 (not shown) of the EUV lithography system 100 of FIG. 1. Alternatively, in some embodiments, the exposure device 202 includes one or more transparent windows (1102a, 1102b) (e.g., see FIG. 11A) that may allow first radiation 608a to enter the exposure device 202 and second radiation 608b to exit the exposure device 202 without the need to install the source 606 and detector 610 directly within the exposure device 202. Various other configurations of the source 606 and detector 610 within or externally to the EUV lithography system 100 may be provided in other embodiments.

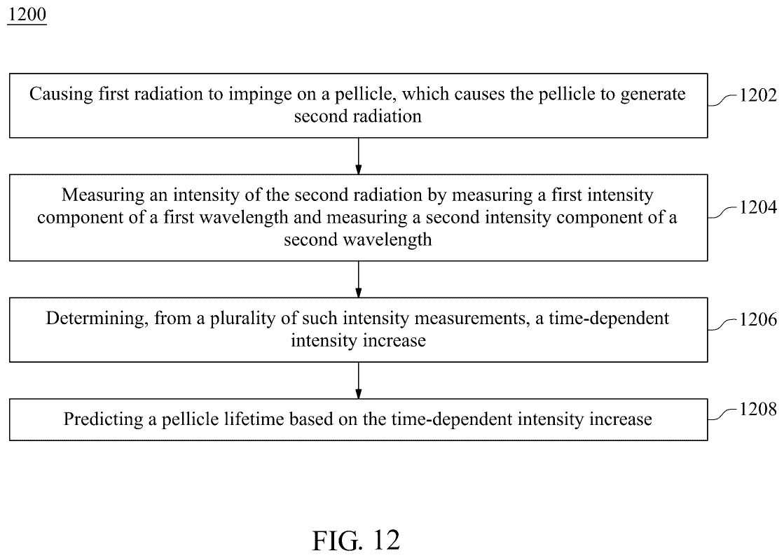

FIG. 12 is a flowchart illustrating operations of a method 1200 of inspecting a pellicle 65, according to various embodiments. The method 1200 includes generating a plurality of intensity measurements by repeatedly performing a corresponding plurality of operations (1202, 1204) as follows. In operation 1202, the method 1200 includes causing first radiation 608a to impinge on the pellicle 65, which causes the pellicle 65 to generate second radiation 608b. In operation 1204, the method 1200 includes measuring an intensity of the second radiation 608b. In operation 1206, the method 1200 includes determining, from the plurality of intensity measurements, a time-dependent intensity increase. In operation 1208, the method 1200 includes predicting a pellicle lifetime based on the time-dependent intensity increase. According to some embodiments, in measuring the intensity according to operation 1204, the method 1200 further includes measuring a first intensity component 810a of a first wavelength and measuring a second intensity component 810b of a second wavelength.

According to some embodiments, in measuring the intensity according to operation 1204, the method 1200 further includes measuring two or more wavelengths including 402 nm, 425 nm, 450 nm, 475 nm, 515 nm, 550 nm, 555 nm, 600 nm, 640 nm, 690 nm, 745 nm, and 855 nm. In some embodiments, the method 1200 further includes generating the first radiation 608a to include a third wavelength that is different from at least one of the first wavelength and the second wavelength. In some embodiments, the method 1200 further includes generating the first radiation 608a to include a third wavelength that is from 150 nm to 350 nm. In further embodiments, the method 1200 includes generating the first radiation 608a to include a white light spectrum. In some embodiments, the method 1200 further includes generating the first radiation 608a to include a third wavelength that is from 495 nm to 570 nm.

According to some embodiments, in predicting the pellicle lifetime according to operation 1208, the method 1200 further includes determining a correlation between the time-dependent intensity increase of the second radiation 608b and a corresponding material property, such as a transmissivity of the pellicle 65 to radiation including an extreme ultraviolet wavelength. According to some embodiments, the pellicle 65 includes a layer of carbon nanotubes, the extreme ultraviolet wavelength is 13.5 nm, and predicting the pellicle lifetime according to operation 1208 of the method 1200 further includes determining at least one of a thickness or a density of the layer of carbon nanotubes.

According to some embodiments, the pellicle 65 is installed on a reticle 80 within a lithography machine 100, and the plurality of intensity measurements, performed in operation 1204 of the method 1200, are made using a source 606 of the first radiation 608a and a detector 610 of the second radiation 608b that are installed within the lithography machine 100. According to some embodiments, the pellicle 65 is installed on a reticle 80 that is held in a reticle pod 602, and the plurality of intensity measurements, performed in operation 1204 of the method 1200, are made using a source 606 of the first radiation 608a and a detector 610 of the second radiation 608b that are each located externally to the reticle pod 602.

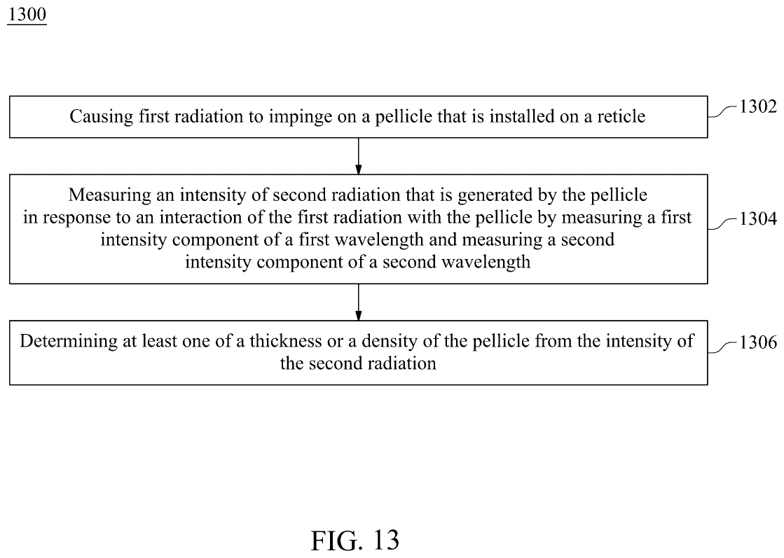

FIG. 13 is a flowchart illustrating operations of a method 1300 of inspecting a lithography system component, according to various embodiments. In operation 1302, the method 1300 includes causing first radiation 608a to impinge on a pellicle 65 that is installed on a reticle 80. In operation 1304, the method 1300 includes measuring an intensity of second radiation 608b that is generated by the pellicle 65 in response to an interaction of the first radiation 608a with the pellicle 65. In operation 1306, the method 1300 includes determining at least one of a thickness or a density of the pellicle 65 from the intensity of the second radiation 608b. According to some embodiments, in measuring the intensity of the second radiation 608b according to operation 1304, the method 1300 further includes measuring a first intensity component 810a of a first wavelength and measuring a second intensity component 810b of a second wavelength.

According to some embodiments, the pellicle 65 and the reticle 80 are installed within a lithography machine 100, and intensity is measured, in operations 1302 and 1304 of the method 1300, using a source 606 of the first radiation 608a and a detector 610 of the second radiation 608b that are each installed within the lithography machine 100. According to some embodiments, the pellicle 65 and the reticle 80 are held in a reticle pod 602, and intensity is measured in operations 1302 and 1304 of the method 1300, using a source 606 of the first radiation 608a which is located internally to the reticle pod 602 and a detector 610 of the second radiation 608b which is located externally to the reticle pod 602.

According to some embodiments, the method 1300 further includes generating the first radiation 608a to include one of a third wavelength that is from 150 nm to 350 nm; a third wavelength that is from 495 nm to 570 nm; or a plurality of wavelengths including a white light spectrum. According to some embodiments, measuring the intensity of the second radiation 608b, in operations 1302 and 1304 of the method 1300, further includes measuring two or more wavelengths including 402 nm, 425 nm, 450 nm, 475 nm, 515 nm, 550 nm, 555 nm, 600 nm, 640 nm, 690 nm, 745 nm, and 855 nm. According to some embodiments, the pellicle 65 includes a layer of carbon nanotubes, and the method 1300 further includes predicting a pellicle lifetime based on a pre-determined correlation between values of the intensity of second radiation 608b and a corresponding material property, such as a transmissivity of the pellicle 65 to radiation including a wavelength of 13.5 nm.

Referring to all drawings and according to various embodiments of the present disclosure, a lithography system component (65, 80, 606, 610) is provided. The lithography system component (65, 80, 606, 610) includes a reticle 80, a pellicle 65 that is installed on the reticle 80, a source 606 of first radiation 608a configured to cause the first radiation 608a to impinge on the reticle 80, and a detector 610 that is configured to measure second radiation 608b that is generated by the pellicle 65 in response to an interaction of the first radiation 608a with the pellicle 65. According to some embodiments, the detector 610 is further configured to measure a first intensity component 810a of a first wavelength and a second intensity component 810b of a second wavelength of the second radiation 608b.

According to some embodiments, the source 606 of the first radiation 608a is configured to generate the first radiation 608a including one of a third wavelength that is from 150 nm to 350 nm, a third wavelength that is from 495 nm to 570 nm, or a plurality of wavelengths including a white light spectrum. Further, according to some embodiments, the detector 610 is configured to measure intensities of two or more wavelengths including 402 nm, 425 nm, 450 nm, 475 nm, 515 nm, 550 nm, 555 nm, 600 nm, 640 nm, 690 nm, 745 nm, and 855 nm. According to various embodiments, the pellicle 65 includes a layer of carbon nanotubes and the detector 610 further includes processing circuits that are configured to generate a spectral profile of the received second radiation.

Disclosed embodiments are advantageous by providing methods of performing non-destructive inspection of pellicles 65 for EUV lithography while an EUV reticle 80 is installed within an EUV lithography machine 100 or while the reticle 80 is secured within a protective reticle pod 602. EUV pellicles 65 that contain CNTs have many desirable properties for EUV lithography applications, including high transmittance of EUV radiation, long lifetime, mechanical strength, effective blocking of particulates, and efficient heat dissipation. Despite these advantages, CNT pellicles 65 used in EUV lithography are susceptible to damage from the intense EUV radiation. Such damage can contaminate the EUV lithography machine leading to downtime required to perform lengthy and sometimes expensive repairs. Disclosed embodiments provide methods of predicting pellicle lifetime using non-destructive radiation (608a, 608b) based on a correlation between pellicle thickness and/or density and measured transmittance (e.g., see FIG. 5) of the non-destructive (i.e., non-EUV) radiation (608a, 608b).

According to various embodiments, a method of inspecting a pellicle is provided. The method includes generating a plurality of intensity measurements by performing a corresponding plurality of operations, with each of the corresponding plurality of operations including causing first radiation to impinge on the pellicle, which causes the pellicle to generate second radiation; and measuring an intensity of the second radiation. The method further includes determining, from the plurality of intensity measurements, a time-dependent intensity increase; and predicting a pellicle lifetime based on the time-dependent intensity increase. According to various embodiments, measuring the intensity of the second radiation further includes measuring a first intensity component of a first wavelength and measuring a second intensity component of a second wavelength.

According to various embodiments, measuring the intensity of the second radiation further includes measuring two or more wavelengths including 402 nm, 425 nm, 450 nm, 475 nm, 515 nm, 550 nm, 555 nm, 600 nm, 640 nm, 690 nm, 745 nm, and 855 nm. According to various embodiments, the method further includes generating the first radiation to include a third wavelength that is different from at least one of the first wavelength and the second wavelength. According to various embodiments, the method further includes generating the first radiation to include a third wavelength that is from 150 nm to 350 nm. According to various embodiments, the method further includes generating the first radiation to include a white light spectrum. According to various embodiments, the method further includes generating the first radiation to include a third wavelength that is from 495 nm to 570 nm. According to various embodiments, predicting the pellicle lifetime further includes determining a correlation between the time-dependent intensity increase of the second radiation and a corresponding material property, such as a transmissivity of the pellicle to radiation including an extreme ultraviolet wavelength.

According to various embodiments, the pellicle includes a layer of carbon nanotubes, the extreme ultraviolet wavelength is 13.5 nm, and predicting the pellicle lifetime further includes determining at least one of a thickness or a density of the layer of carbon nanotubes. According to various embodiments, the pellicle is installed on a reticle within a lithography machine and the plurality of intensity measurements are made using a source of the first radiation and a detector of the second radiation that are installed within the lithography machine. According to various embodiments, the pellicle is installed on a reticle that is held in a reticle pod, and the plurality of intensity measurements are made using a source of the first radiation and a detector of the second radiation that are each located externally to the reticle pod.

According to various embodiments, a method of inspecting a lithography system component is provided. The method includes causing first radiation to impinge on a pellicle that is installed on a reticle; measuring an intensity of second radiation that is generated by the pellicle in response to an interaction of the first radiation with the pellicle; and determining at least one of a thickness or a density of the pellicle from the intensity of the second radiation. According to various embodiments, measuring the intensity of the second radiation further includes measuring a first intensity component of a first wavelength and measuring a second intensity component of a second wavelength. According to various embodiments, the pellicle and the reticle are installed within a lithography machine and the intensity is measured using a source of the first radiation and a detector of the second radiation that are each installed within the lithography machine. According to various embodiments, the pellicle and the reticle are held in a reticle pod, and intensity is measured using a source of the first radiation that is located internally to the reticle pod and a detector of the second radiation that is located externally to the reticle pod.

According to various embodiments, the method further includes generating the first radiation to include one of a third wavelength that is from 150 nm to 350 nm, a third wavelength that is from 495 nm to 570 nm, or a plurality of wavelengths including a white light spectrum. According to various embodiments, measuring the intensity of the second radiation further includes measuring two or more wavelengths including 402 nm, 425 nm, 450 nm, 475 nm, 515 nm, 550 nm, 555 nm, 600 nm, 640 nm, 690 nm, 745 nm, and 855 nm. According to various embodiments, the pellicle includes a layer of carbon nanotubes, and the method further includes predicting a pellicle lifetime based on a pre-determined correlation between values of the intensity of second radiation and a corresponding material property, such as a transmissivity of the pellicle to radiation including a wavelength of 13.5 nm.

According to various embodiments, a lithography system component is provided. The lithography system component includes a reticle, a pellicle that is installed on the reticle, a source of first radiation configured to cause the first radiation to impinge on the reticle, and a detector that is configured to measure second radiation that is generated by the pellicle in response to an interaction of the first radiation with the pellicle. According to various embodiments, the detector is further configured to measure a first intensity component of a first wavelength and a second intensity component of a second wavelength of the second radiation.

According to various embodiments, the source of the first radiation is configured to generate the first radiation including one of a third wavelength that is from 150 nm to 350 nm, a third wavelength that is from 495 nm to 570 nm, or a plurality of wavelengths including a white light spectrum. According to various embodiments, the detector is configured to measure intensities of two or more wavelengths including 402 nm, 425 nm, 450 nm, 475 nm, 515 nm, 550 nm, 555 nm, 600 nm, 640 nm, 690 nm, 745 nm, and 855 nm. According to various embodiments, the pellicle includes a layer of carbon nanotubes and the detector further includes processing circuits that are configured to generate a spectral profile of the received second radiation.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of inspecting a pellicle, comprising:
generating a plurality of intensity measurements by performing a corresponding plurality of operations, wherein each of the corresponding plurality of operations comprises:
causing first radiation to impinge on the pellicle, which causes the pellicle to generate second radiation; and
measuring an intensity of the second radiation;
determining, from the plurality of intensity measurements, a time-dependent intensity increase; and
predicting a pellicle lifetime based on the time-dependent intensity increase,
wherein measuring the intensity of the second radiation further comprises measuring a first intensity component of a first wavelength and measuring a second intensity component of a second wavelength.

2. The method of claim 1, wherein measuring the intensity of the second radiation further comprises measuring two or more wavelengths selected from the group consisting of 402 nm, 425 nm, 450 nm, 475 nm, 515 nm, 550 nm, 555 nm, 600 nm, 640 nm, 690 nm, 745 nm, and 855 nm.

3. The method of claim 1, further comprising generating the first radiation to comprise a third wavelength that is different from at least one of the first wavelength and the second wavelength.

4. The method of claim 1, further comprising generating the first radiation to comprise a third wavelength that is from 150 nm to 350 nm.

5. The method of claim 1, further comprising generating the first radiation to comprise a white light spectrum.

6. The method of claim 1, further comprising generating the first radiation to comprise a third wavelength that is from 495 nm to 570 nm.

7. The method of claim 1, wherein predicting the pellicle lifetime further comprises determining a correlation between the time-dependent intensity increase of the second radiation and a corresponding material property,
wherein the corresponding material property comprises a transmissivity of the pellicle to radiation comprising an extreme ultraviolet wavelength.

8. The method of claim 7, wherein:
the pellicle comprises a layer of carbon nanotubes; and
predicting the pellicle lifetime further comprises determining at least one of a thickness or a density of the layer of carbon nanotubes.

9. The method of claim 1, wherein:
the pellicle is installed on a reticle within a lithography machine; and
the plurality of intensity measurements are made using a source of the first radiation and a detector of the second radiation that are installed within the lithography machine.

10. The method of claim 1, wherein:
the pellicle is installed on a reticle that is held in a reticle pod; and
the plurality of intensity measurements are made using a source of the first radiation and a detector of the second radiation that are each located externally to the reticle pod.

11. A method of inspecting a lithography system component, comprising:
causing first radiation to impinge on a pellicle that is installed on a reticle;
measuring an intensity of second radiation that is generated by the pellicle in response to an interaction of the first radiation with the pellicle; and
determining at least one of a thickness or a density of the pellicle from the intensity of the second radiation,
wherein measuring the intensity of the second radiation further comprises measuring a first intensity component of a first wavelength and measuring a second intensity component of a second wavelength.

12. The method of claim 11, wherein:
the pellicle and the reticle are installed within a lithography machine; and
the intensity is measured using a source of the first radiation and a detector of the second radiation that are each installed within the lithography machine.

13. The method of claim 11, wherein:
the pellicle and the reticle are held in a reticle pod; and
the intensity is measured using a source of the first radiation that is located internally to the reticle pod and a detector of the second radiation that is located externally to the reticle pod.

14. The method of claim 11, further comprising generating the first radiation to comprise one of:
a third wavelength that is from 150 nm to 350 nm;
a third wavelength that is from 495 nm to 570 nm; or
a plurality of wavelengths comprising a white light spectrum.

15. The method of claim 11, wherein measuring the intensity of the second radiation further comprises measuring two or more wavelengths selected from the group consisting of 402 nm, 425 nm, 450 nm, 475 nm, 515 nm, 550 nm, 555 nm, 600 nm, 640 nm, 690 nm, 745 nm, and 855 nm.

16. The method of claim 11, wherein the pellicle comprises a layer of carbon nanotubes, the method further comprising:
predicting a pellicle lifetime based on a pre-determined correlation between values of the intensity of second radiation and a corresponding material property,
wherein the corresponding material property comprises a transmissivity of the pellicle to radiation comprising a wavelength of 13.5 nm.

17. A lithography system component, comprising:
a reticle;
a pellicle installed on the reticle;
a source of first radiation configured to cause the first radiation to impinge on the reticle; and
a detector that is configured to measure second radiation that is generated by the pellicle in response to an interaction of the first radiation with the pellicle,
wherein the detector is further configured to measure a first intensity component of a first wavelength and a second intensity component of a second wavelength of the second radiation.

18. The lithography system component of claim 17, wherein:
the source of the first radiation is configured to generate the first radiation comprising one of:
a third wavelength that is from 150 nm to 350 nm;
a third wavelength that is from 495 nm to 570 nm; or
a plurality of wavelengths comprising a white light spectrum; and
the detector is configured to measure intensities of two or more wavelengths selected from the group consisting of 402 nm, 425 nm, 450 nm, 475 nm, 515 nm, 550 nm, 555 nm, 600 nm, 640 nm, 690 nm, 745 nm, and 855 nm.

19. The lithography system component of claim 17, wherein the pellicle comprises a layer of carbon nanotubes.

20. The lithography system component of claim 17, wherein the detector further includes processing circuits that are configured to generate a spectral profile of the second radiation.
